(19) United States
(12) Patent Application Publication
(10) Pub. No.: US 2018/0254648 A1
(43) Pub. Date: Sep. 6, 2018

(54) Applying Alternate Modes of USB Type-C for Fast Charging Systems

(71) Applicant: Dialog Semiconductor (UK) Limited, London (GB)

(72) Inventor: Lasse Harju, Munich (DE)

(21) Appl. No.: 15/446,131

(22) Filed: Mar. 1, 2017

(51) Int. Cl. H02J 7/00; G01R 31/36

(52) U.S. Cl. CPC H02J 7/0052; H02J 2007/0062; G01R 31/362; H02J 7/007

(57) ABSTRACT

A system for charging a battery of an electronic device is presented. The system uses a power adaptor, with USB interfaces in the electronic device and in the power adaptor. The electronic device includes a charging control unit coupled with the first USB interface and the battery. The charging control unit receives an analog charging parameter of the charging system and forwards this parameter to an analog data port of the first USB interface. The charging control unit is controlled by a control signal received from the power adaptor. The power adaptor comprises a power converter to convert a mains voltage to a USB supply voltage to be provided to the electronic device via a power supply port of the first and the second USB interface. The power adaptor also includes a controller to control the power converter to allow charging of the battery using the USB supply voltage.

### TECHNICAL FIELD

The present document relates to a reliable battery charging system with an efficient charging control mechanism.

### BACKGROUND

Traditionally, the safety of battery charging systems has been ensured by following the guidelines of Japan Electronics & Information Technology Industries Association (JEITA) for battery powered systems and by using standardized cables and connectors. The JEITA guidelines cover safe voltage, current and temperature ranges for batteries and the necessary safety measures in charging systems to prevent over-charge, over-discharge and over-temperature. The current capability of a cable connecting to a travel adaptor and a mobile device is commonly ensured by using standardizes cables, e.g. Universal Serial Bus (USB)

Type-C cables. The mechanical construction of the cables together with the USB compliancy program ensures, to some extent, that the cables sold in the market do not cause safety issues if operated within the allowed current rating. Besides, the charging circuitries in a travel adaptor and in a mobile device make sure that these ratings are not violated during charging.

However, increase of charging rates re-emphasizes the safety of battery charging systems. Charging systems which expose a cable to higher currents than normally to increase charging rates may put more stress on the cable. For example, increase of charging rates puts more stress on the charging cable, connectors and the battery technology. Even lower charging rates may cause safety issues because of sub-quality cables and connectors, wear and tear of connectors and dirt in connectors. Due to lack of reliable methods for detecting fault conditions, charging systems which increase the charging rates while keeping traditional safety measures may result in increased risk of safety hazards during charging.

### SUMMARY

There is a need for new safety features to improve the safety of battery charging systems. In particular, there is a need for a real-time charging control mechanism which allows reliable fault detection to be applied in a battery charging system for safety improvement. In view of this need, the present document discloses apparatuses and methods to implement a reliable battery charging mechanism for an electronic device. In particular, a battery charging mechanism having the features of the respective independent claims for monitoring battery charging and detecting fault condition accordingly is proposed, so as to improve the safety of a battery charging system.

According to an aspect of the disclosure, a control unit for monitoring charging of a battery of an electronic device is provided. The control unit may be disposed/placed in the electronic device, for example, a mobile/portable electronic device such as a mobile phone, a tablet computer, and so on. In general, the control unit may be included in a charging unit or a charger of the electronic device. The charging unit or the charger of the electronic device may supply an electrical current or voltage to the battery of the electronic device to charge the battery. Moreover, the electronic device may have a Universal Serial Bus (USB) controller which may connect to a USB port for data and/or power transmission between the electronic device and an external device. In particular, the USB controller may be a USB type C device (having or being compatible with mechanical and electrical properties of connectors and cables as defined in the USB type C specification) operating in an alternate mode.

In detail, the control unit comprises a control input, at least one sensing input port, a sensing output port and a control logic. The control input is configured for receiving a control signal from a USB controller of the electronic device. Alternatively or in addition, the control input may be implemented via a software (SW) control that reads a status of the USB controller and updates a control register of the control unit accordingly. In an embodiment, the SW control may accesses devices (e.g. the control unit and the USB controller) via an I2C (inter-integrated circuit) bus. The control signal may be provided based on data transmission between the USB controller of the electronic device and an external device, e.g. a power adaptor. For example, the USB controller of the electronic device may communicate with the external device according to a USB protocol, and transmission of USB commands may be performed between the USB controller and the external device via an USB interface (port) that may be used for connecting the electronic device with the external device. Accordingly, the USB controller may provide the control signal to the control input of the control unit based on the USB commands. It should be noted that the data transmission between the USB controller and the external device may be performed via one or more digital ports of the USB interface.

More specifically, the proposed battery charging mechanism may comprise a direct charging mechanism. That is, the battery of the electronic device may be charged directly by a USB supply voltage (V_{BUS}) via the USB interface. Herein, a USB supply voltage (V_{BUS}) may be provided by an external device (e.g. a travel/power adaptor) via the USB interface directly to the battery through a bypass path (e.g. a path connecting the battery to the USB interface so that the USB supply voltage (V_{BUS}) can be directly applied to the battery for charging without passing the charger of the electronic device) which may be enabled using a switch, e.g. a power switch. Accordingly, the control unit may further comprise a zo direct charging switch driving port for providing a drive signal to the power switch (for the bypass path) to enable direct charging of the battery from the USB supply voltage (V_{BUS}). Alternatively, the control unit may also include a fixed scaler (e.g. a high efficiency fixed scaler) or may include a port for controlling the (high efficiency) fixed scaler to implement direct charging. In some embodiments, the proposed battery charging mechanism may be a normal charging mechanism where the USB supply voltage (V_{BUS}) may be applied to the battery for charging through the charger of the electronic device. In further detail, the at least one sensing input port of the control unit is configured for sensing an analog charging parameter of the battery. In particular, the at least one sensing input port may connect to the USB interface to sense the USB supply voltage (V_{BUS}) provided by the USB interface to the battery and/or the at least one sensing input port may connect to the battery to sense a battery charging voltage (V_{BAT}) of the battery. Thus, the analog charging parameter of the battery may be sensed based on e.g. the USB supply voltage (V_{BUS}) and/or the battery charging voltage (V_{BAT}). It is appreciated that, in addition to the examples of using the USB supply voltage (V_{BUS}) and/or the battery charging voltage (V_{BAT}) for the analog charging parameter, other parameters like the charging current of the battery may be sensed as the analog charging parameter of the battery. Further, any information that allows detecting the voltage drop across a USB cable may be used as charging parameter.

Moreover, the sensing output port of the control unit is configured for providing an analog sensing output signal to the USB interface. In particular, the analog sensing output signal may be provided at an analog port of the USB interface to be sent to the power adaptor. The sensing output port may be configured to continuously output (using the analog sensing output signal) the sensed analog charging parameter of the battery to be further sent to the power adaptor via the USB interface. To achieve this, the control logic of the control unit is configured for coupling the at least one sensing input port with the sensing output port upon receiving the control signal. In other words, the control logic of the control unit may connect a sensing input port with the sensing output port based on the control signal received from the USB controller. Alternatively or in addition, the connection between a sensing input port and the sensing output port may be established based on a software (SW) control. Similar to the SW control for performing the function of the control input, the SW control for connecting the sensing input port with the sensing output port may also update one or more control registers of the control unit accordingly. In an embodiment, an I2C interface may be featured through which the SW control can set the register(s).

In some embodiments, the control unit may further comprise a plurality of sensing input ports and a switching unit. The switching unit may be coupled with the plurality of sensing input ports and the sensing output port. Also, the switching unit may be controlled by the control logic to select one of the sensing input ports and to pass a selected sensing input signal (which may be associated with the selected sensing input port) to the sensing output port. In particular, the selected sensing input signal may be used for carrying a corresponding sensed analog charging parameter of the battery. That is, the selected sensing input signal may be associated with e.g. the USB supply voltage (V_{BUS}) and/or the battery charging voltage (V_{BAT}). Moreover, the control logic may be configured to control the switching unit based upon the control signal, and a sensed analog charging parameter of the battery may be selected to be output to the USB interface according to a command associated with the control signal which is received from the USB controller.

In some embodiments, the USB supply voltage (V_{BUS}) may be provided to the battery through the control unit for battery charging. Herein, the control unit may also comprise a power input port coupled with the USB supply voltage (V_{BUS}), a battery charging unit for generating a battery charging voltage (V_{BAT}), and a battery charging port coupled with the battery for charging the battery. The control unit may supply the battery charging voltage (V_{BAT}) to the battery via the battery charging port. In some embodiments, the control unit may further comprise a voltage protection unit for preventing the battery charging unit from generating the battery charging voltage (V_{BAT}) in case the USB supply voltage (V_{BUS}) is higher than a protection threshold.

As a result, by selecting a suitable charging parameter of the battery to be output to the power adaptor, it is possible to monitor battery charging conditions at the power adaptor without requiring the data communication (e.g. according to USB type C specification) between the electronic device and the power adaptor. Thereby, the battery charging conditions can be more efficiently and more reliably monitored (e.g. real-time monitoring) during direct charging of the battery, especially when the data transmission between the electronic device and the power adaptor is failed.

According to another aspect of the disclosure, a charging arrangement for charging a battery of an electronic device is provided. In general, the electronic device may be a mobile or portable electronic device, for example, a mobile phone or a tablet computer. The charging arrangement may be included in the electronic device for providing electrical current or voltage to the battery of the electronic device to charge the battery. According to the disclosure, the charging arrangement comprises a Universal Serial Bus (USB) interface and a charging control unit.

The USB interface is configured for connecting the electronic device via a USB cable with a power adaptor or other power supply devices. In detail, the USB interface comprises a power supply port providing a USB supply voltage (V_{BUS}) and at least one analog data port, i.e., a port applicable for DC voltage signaling or DC current signaling. As mentioned above, the USB supply voltage (V_{BUS}) may be provided by the power adaptor via the power supply port of the USB interface to charge the battery of the electronic device. The at least one analog data port may be used for communicating one or more analog signals between the electronic device and the power adaptor. Additionally, the USB interface may comprise at least one digital data port for communicating one or more digital signals (data) between the electronic device and the power adaptor.

The charging control unit is coupled with the USB interface and the battery. The charging control unit of the charging arrangement may be similar to the proposed control unit as indicated above or may perform similar functions as the proposed control unit as described above. In particular, the charging control unit may receive at least one analog charging parameter of the battery and forward the at least one analog charging parameter to the at least one analog data port of the USB interface. Similar to the control unit as indicated above, the charging control unit may receive the USB supply voltage (V_{BUS}) provided by the power supply port of the USB interface and the received analog charging parameter may be related to the USB supply voltage (V_{BUS}). Further, the charging control unit may be controlled by a control signal received via the USB interface. For example, the USB interface may communicate with the charging control unit using USB commands carried by the control signal, and the control signal may be a digital signal provided at a digital port of the USB interface or received via the at least one digital data port of the USB interface.

In some embodiments, the battery of the electronic device may be charged using direct charging mechanism. The charging arrangement may further comprise a power switch to enable direct charging of the battery from the USB supply voltage (V_{BUS}), and the power switch may be controlled by the charging control unit. Alternatively, direct charging may be also implemented by connecting the USB supply voltage to the battery via a high efficiency fixed scaler instead of a simple switch. In some embodiments, the charging arrangement may also comprise a USB controller coupled with the USB interface and the charging control unit. The USB controller may perform data and/or power transmission between the electronic device and the power adaptor. More specifically, the USB controller may communicate with the power adaptor via a USB protocol (for receiving USB commands) and further control the charging control unit based upon received USB commands. For example, the USB controller may be a USB type C device operating in an alternate mode. In particular, the alternate mode may be entered in response to digital communication between the USB controller and the power adaptor. In some embodiments, the battery of the electronic device may be charged using normal charging mechanism.

In further detail, the charging arrangement may further comprise a multiplexer for multiplexing analog signals from the USB controller to the at least one analog data port of the USB interface. Alternatively, the multiplexer may be configured for multiplexing analog signals from the charging control unit to the at least one analog data port of the USB interface. In particular, the multiplexer may be controlled for forwarding the at least one analog charging parameter to the at least one analog data port of the USB interface. In some embodiments, the charging control unit may comprise an output port for providing the at least one analog charging parameter to the USB controller for forwarding the at least one analog charging parameter to the at least one analog data port of the USB interface. In some embodiments, the charging control unit may comprise an output port for providing the at least one analog charging parameter to the multiplexer for forwarding the at least one analog charging parameter to the at least one analog data port of the USB interface without involvement of the USB controller (i.e. the providing of the analog charging parameter(s) is independent from the operation of the USB controller so that the charging of the battery can be performed independently without being controlled/triggered by a processor of the USB controller).

In some embodiments, the USB interface may comprises a USB type C receptacle, and the at least one analog data port may be a sideband use (SBU) port of the USB interface or the USB type C receptacle. Accordingly, the at least one analog charging parameter may be forwarded to the at least one analog data port of the USB interface via a sideband use (SBU) signal to be received at a SBU port of the USB type C receptacle transmitted via the SBU port to the power adaptor. In some embodiments, the charging arrangement may further comprise a voltage protection unit for preventing the charging control unit from charging of the battery from the USB supply voltage in case the USB supply voltage (V_{BUS}) is higher than a protection threshold.

As a result, the proposed charging arrangement enables efficient monitoring of battery charging conditions by forwarding, in real-time and continuously, the charging parameter of the battery to the power adaptor. By this way, fault conditions during (direct) charging can be immediately identified despite unsuccessful (digital) data transmission between the electronic device and the power adaptor, which can avoid safety hazards caused by high stress put on the cable during direct charging.

According to another aspect of the disclosure, a power adaptor for supplying power via a USB cable to an electronic device is provided. For example, the electronic device may be a mobile/portable electronic device such as a mobile phone, a tablet computer, and so on, and the power adaptor may comprise a travel adaptor suitable for the mobile/portable electronic device. In other words, the proposed power adaptor may be used for the electronic device including the control unit or the charging arrangement as described above. According to the disclosure, the power adaptor comprises a power converter configured to convert a mains voltage to a USB supply voltage (V_{BUS}) and a USB interface configured to couple the power adaptor with the electronic device. Furthermore, the power adaptor comprises a controller to control the power converter to control an output voltage and an output current limit of the power adaptor and/or to allow direct charging of a battery in the electronic device.

In particular, the controller may be coupled to at least one analog data port of the USB interface to receive at least one analog charging parameter of the battery. As mentioned above, the USB supply voltage (V_{BUS}) may be provided for charging the battery of the electronic device, and the at least one analog charging parameter of the battery may be associated with the USB supply voltage (V_{BUS}). Further, the controller may be configured to control the power converter during charging of the battery based upon the at least one analog charging parameter. For example, the controller may be configured to modify the USB supply voltage (V_{BUS}) based on the at least one analog charging parameter by controlling the power converter during charging of the battery. In more detail, the controller may be configured to measure a voltage drop across the USB cable based on the at least one analog charging parameter. For example, the voltage drop across the USB cable may be determined by measuring a voltage difference between a USB supply voltage (V_{BUS}) provided by the power adaptor and a USB supply voltage (V_{BUS}) obtained at the electronic device (i.e. the voltage difference in USB supply voltage between one end of the USB cable coupled to the power adaptor and the other end of the USB cable coupled to the electronic device). Subsequently, the controller may be configured to compare the voltage drop with a threshold voltage and to disconnect the power converter from a power supply port of the USB interface in case the measured voltage drop exceeds the threshold voltage, so that the USB supply voltage (V_{BUS}) is not provided to the electronic device for (direct) charging the battery. By this way, an appropriate USB supply voltage can be provided or a USB supply voltage can be disabled according to the circumstances in case of problems (e.g. high cable resistance given by poor-quality cables may cause safety issues) occurring during battery charging, e.g. too high charging voltage/current applied to the battery during direct charging.

In some embodiments, the power adaptor may further comprise a USB controller to perform digital communication according to a USB protocol with the electronic device via the USB interface. In particular, the power adaptor may be configured to enter an USB alternate mode based upon the digital communication between the USB controller and the electronic device. In this case, the electronic device may also enter the USB alternate mode. In some embodiments, the USB controller may be configured to communicate one or more control signals to the electronic device for enabling and/or controlling (direct) charging of the battery. Moreover, a control signal sent to the electronic device may comprise information for selection of an analog charging parameter for being monitored and feed back by the electronic device.

It should be noted that the USB interface of the power adaptor may be similar to the USB interface of the charging arrangement as described above. In particular, the USB interface may comprise a USB type C receptacle. Accordingly, the at least one analog charging parameter of the battery may be provided via a sideband use (SBU) signal received at a SBU port of the USB type C receptacle. Furthermore, the power converter may comprise a power controller and a bridge rectifier. In some embodiments, the controller may be configured to disconnect the power supply port of the USB interface from the power controller in case the measured voltage drop exceeds the threshold voltage.

As a result, by monitoring the charging parameter of the battery in real-time and dynamically modifying the USB supply voltage in response to the monitored charging parameter, the proposed power adaptor can provide a reliable charging mechanism compared to conventional methods. Especially in case of direct charging of the battery, observing the battery charging conditions (e.g. the battery charging current or voltage) at all times and adjusting the USB supply voltage and current limit accordingly can reduce risk of safety hazards which may occur during the direct charging procedure (e.g. over-charge, over-discharge, over-temperature etc.).

According to a further aspect of the disclosure, a charging system for charging a battery of an electronic device using a power adaptor is provided. As mentioned above, the electronic device may be a mobile/portable electronic device such as a mobile phone, a tablet computer, and so on, and the power adaptor may comprise a travel adaptor suitable for the mobile/portable electronic device. It is appreciated that the charging system may have a similar charging element as the proposed charging arrangement as described above. The charging system may also have a similar supplying element as the proposed power adaptor as described above. The charging system may perform similar functions as the proposed charging arrangement and/or the proposed power adaptor as described above.

More specifically, the charging system comprises a first communications interface disposed at the electronic device and a second communications interface disposed at the power adaptor for connecting the electronic device via a communications cable with the power adaptor. The charging system also comprises a charging control unit coupled with the first communications interface and the battery. In particular, the charging control unit is configured to receive at least one analog charging parameter of the charging system (e.g. at least one analog charging parameter of the battery) and to forward the at least one analog charging parameter to at least one analog data port of the first communications interface. Moreover, the charging control unit may be controlled by a control signal received from the power adaptor via the first communications interface and the second communications interface. The communication between the first and the second communications interfaces may be according to a wired communications protocol, e.g. the USB protocol.

The charging system also comprises a power converter disposed at the power adaptor to convert a mains voltage to a supply voltage to be provided to the electronic device via a power supply port of the first and the second communications interfaces. The charging system further comprises a controller disposed at the power adaptor to control the power converter to allow charging of the battery of the electronic device using the supply voltage (e.g. directing charging or normal charging) In particular, the controller may be coupled to at least one analog data port of the second communications interface to receive the at least one analog charging parameter of the charging system via the first communications interface. Also, the controller is configured to control the power converter during charging of the battery based upon the at least one analog charging parameter. In order to achieve a direct charging process, the electronic device may comprise a power switch or a high efficiency fixed scaler controlled by the charging control unit to enable direct charging of the battery from the supply voltage which may be the USB supply voltage (V_{BUS}).

In some embodiments, the charging system may further comprise, in the electronic device, a communications controller coupled with the first communications interface and the charging control unit. In particular, the communications controller may communicate with the controller of the power adaptor according to a communications protocol (e.g. the USB protocol) via the first and the second communications interface. For example, the control signal for controlling the charging control unit may comprise received commands, and the communications controller may be configured to further control the charging control unit for enabling and/or controlling (direct) charging of the battery based upon the received commands.

In some embodiments, the electronic device may comprise a multiplexer for multiplexing analog signals from the communications controller or the charging control unit to the at least one analog data port of the first communications interface. In particular, the multiplexer may be controlled by the charging control unit for forwarding the at least one analog charging parameter to the at least one analog data port of the first communications interface. In some embodiments, the communications interfaces may be USB type C devices operating in an alternate mode. It should be noted that the power adaptor and the electronic device may enter the alternate mode based on digital communication between the USB controller and the power adaptor. Accordingly, the at least one analog charging parameter may be forwarded to the at least one analog data port of the first USB interface (from the USB controller or the charging control unit) via a sideband use (SBU) signal. Also, the at least one analog charging parameter may be provided at the at least one analog data port of the second USB interface via a sideband use (SBU) signal. As mentioned above, the SBU signal may be provided at a SBU port of the USB type C devices.

According to the disclosure, the controller may be configured to measure a voltage drop across the cable based on the at least one analog charging parameter (which may be associated with the USB supply voltage (V_{BUS}) or a battery charging voltage). In some embodiments, the controller may be configured to compare the voltage drop with a threshold voltage. The controller may be configured to further disconnect the power converter from a power supply port of the second communications interface in case the measured voltage drop exceeds the threshold voltage, so that the USB supply voltage (V_{BUS}) is not provided to the electronic device for charging the battery.

As a result, the proposed charging system enables real-time monitoring of battery charging conditions by immediately forwarding the charging parameter of the battery to the power adaptor. The skilled person will appreciate that the monitoring of battery charging can be performed merely through an analog signal (via an analog port of the USB interface) and that data communication between the electronic device and the power adaptor (via a digital port of the USB interface) is not necessary for the monitoring, which enables an efficient charging control loop independent from the USB digital communication. Moreover, by further adapting the USB supply voltage for battery charging based on the monitored charging conditions, the proposed charging system performs a reliable charging mechanism which reduces safety hazards caused during the charging procedure (e.g. high charging current/voltage over a damaged cable in case of directing charging of the battery).

According to a further aspect of the disclosure, a method for charging a battery of an electronic device using a power adaptor is provided. In general, the electronic device is coupled with the power adaptor via a USB cable. The electronic device may be a mobile/portable electronic device such as a mobile phone, a tablet computer, and so on, and the power adaptor may comprise a travel adaptor suitable for the mobile/portable electronic device. In particular, the electronic device may be configured to communicate with the power adaptor via a USB power delivery protocol. The proposed method may be implemented in the proposed charging system as described above.

According to the disclosure, the method comprises sending a control signal from the electronic device to the power adaptor via the USB cable. The method comprises converting a mains voltage to a USB supply voltage (V_{BUS}) at the power adaptor and providing the USB supply voltage (V_{BUS}) to the electronic device via the USB cable for performing charging of the battery of the electronic device (e.g. direct charging or normal charging of the battery). Furthermore, the method comprises receiving at least one analog charging parameter of a charging system (e.g. the battery) at the electronic device and forwarding the at least one analog charging parameter to the power adaptor via at least one analog data port of the USB cable. Subsequently, the method comprises receiving the at least one analog charging parameter of the charging system at the power adaptor via the at least one analog data port of the USB cable. The method also comprises controlling the USB supply voltage (V_{BUS}) and output current limit at the power adaptor during (direct) charging of the battery based upon the at least one analog charging parameter.

In some embodiments, the method may further comprise controlling a switch or a fixed scaler (e.g. a high efficiency fixed scaler) at the electronic device to enable direct charging of the battery from the USB supply voltage (V_{BUS}). In some embodiments, the at least one analog charging parameter may be forwarded to the at least one analog data port of the USB cable via a sideband use (SBU) signal. In this case, the SBU signal may be provided at a SBU port of the USB cable. In some embodiments, the method may further comprise multiplexing analog signals from a USB controller or a charging control unit of the electronic device to the at least one analog data port of the USB cable.

As a result, by monitoring the charging parameter of the battery and controlling the USB supply voltage and output current limit according to the monitored charging parameter, the proposed method provides a simple and reliable charging mechanism which can improve the safety of the battery charging systems without relying on data communication between the electronic device and the power adaptor. Although direct charging may be a methodology that benefits from the increased safety the most, but the proposed method can be similarly applied to normal charging as well.

It should be noted that the methods and systems including its preferred embodiments as outlined in the present document may be used stand-alone or in combination with the other methods and systems disclosed in this document. In addition, the features outlined in the context of a system are also applicable to a corresponding method. Furthermore, all aspects of the methods and systems outlined in the present document may be arbitrarily combined. In particular, the features of the claims may be combined with one another in an arbitrary manner.

In the present document, the terms “couple”, “coupled”, “connect”, and “connected” refer to elements being in electrical communication with each other, whether directly connected e.g., via wires, or in some other manner.

### BRIEF DESCRIPTION OF THE DRAWINGS

The application is explained below in an exemplary manner with reference to the accompanying drawings, wherein

FIG. 1a schematically illustrates an example of a direct charging system including a travel adaptor and a mobile device;

FIG. 1b schematically illustrates an example of a direct charging system including a travel adaptor and a mobile device

FIG. 2a schematically illustrates an example of signalling exchange procedure performed between the travel adaptor and the mobile device according to embodiments of the disclosure;

FIG. 2b illustrates an example of a port arrangement of the USB type C receptacle according to embodiments of the disclosure;

FIG. 3a schematically illustrates an example of a battery charging system according to embodiments of the disclosure;

FIG. 3b schematically illustrates an example of a battery charging system according to embodiments of the disclosure; and

FIG. 4 illustrates processing steps for a proposed battery charging method according to embodiments of the disclosure.

### DESCRIPTION

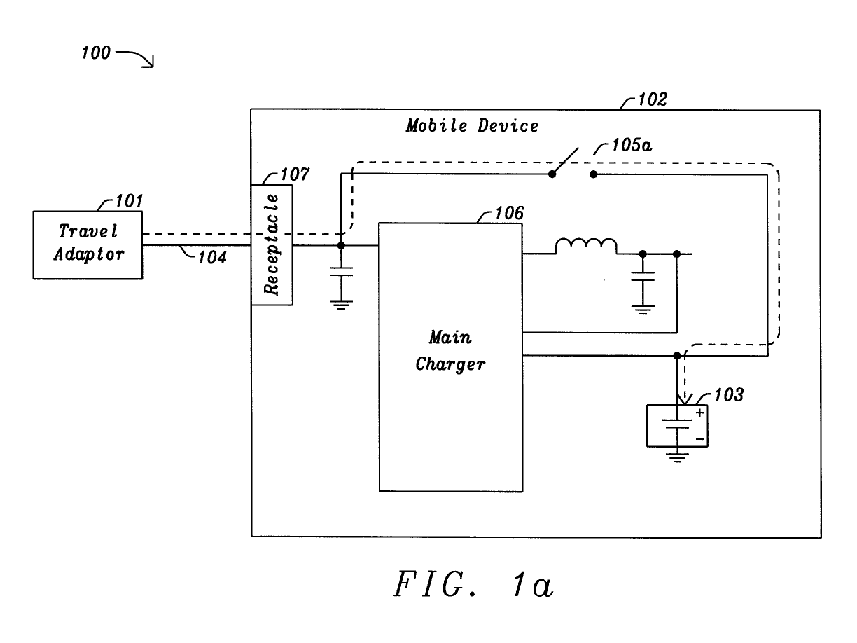

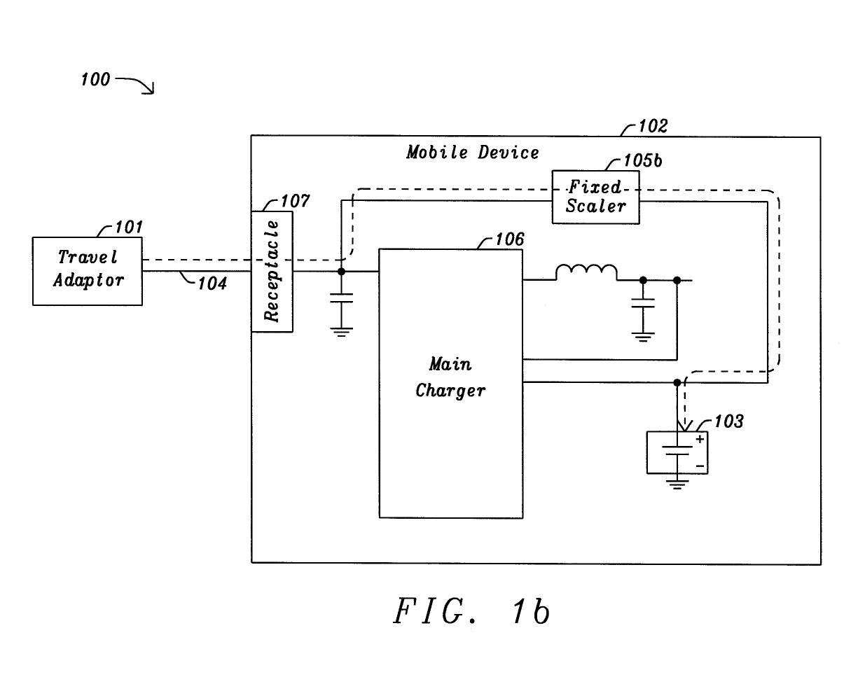

FIG. 1a schematically illustrates an example of a direct charging system 100 including a travel adaptor (TA) 101 and a mobile device 102. The mobile device 102 includes a battery 103 and a main charger 106. Herein, a battery charging topology is applied where the travel adaptor 101 is directly and selectively connected to the battery 103 via a charging cable 104 and an interface, e.g. a receptacle 107. The travel adaptor 101 provides a charging supply voltage to the battery 103 of the mobile device via the receptacle 107 for charging the battery 103. In particular, the mobile device 102 features a bypass, e.g. a switch 105a, for the main charger 106 that connects the TA 101 to the battery 103. When the switch 105a is off (open), the main charger 106 may receive (through e.g. a voltage detecting unit of the main charger 106, not shown) the charging supply voltage provided by the travel adaptor 101 and then provide (through e.g. a battery charging unit of the main charger 106, not shown) a battery charging voltage to the battery 103 for charging. This scenario where the switch 105a is in off state can also be referred as a normal charging of the battery 103 through the main charger 106. On the other hand, when the switch 105a is on (closed), the charging supply voltage provided by the travel adaptor 101 can be directly applied to the battery 103 for charging without passing the main charger 106 to perform a direct charging of the battery 103. By applying a direct charging mechanism, charging rates can be significantly increased to realize a fast charging system.

Alternatively, instead of applying the switch 105a to the bypass, a fixed scaler 105b may be used for the bypass as illustrated in FIG. 1b as another embodiment for implementing the direct charging system 100. In particular, the fixed scaler 105b may be a high efficiency fixed scaler that may include one or more capacitive elements to provide a suitable battery charging voltage to the battery 103 for charging (e.g. converting the charging supply voltage provided by the travel adaptor 101 into the suitable battery charging voltage through an appropriate voltage ratio). By this way, an efficient direct charging mechanism can be performed with reduced power dissipation.

According to some embodiments of the disclosure, the mobile device 102 may be a USB device and the interface 107 may be a USB interface. For example, the mobile device 102 may be a USB Type C device and the interface 107 may be a USB type C receptacle. The USB Type-C specification introduces alternate modes, in which the signals of a Type C cable can be used for other purposes than their original USB functions. When a compatible mobile device is attached to a compatible travel adaptor (e.g. the mobile device 102 connected to the travel adaptor 101), an alternate mode may be entered via standard USB power delivery (PD) signalling and vendor defined messages (VDMs). In general, USB power delivery (PD) specifies vendor defined messages (VDM) that can be used to exchange information which is not covered by the standard power delivery messages. Structured VDMs can be used to achieve finer voltage and current control than normally enabled by PD messaging. Thus, a USB Type C device can enter an alternate mode based on exchanging of PD signalling and VDMs.

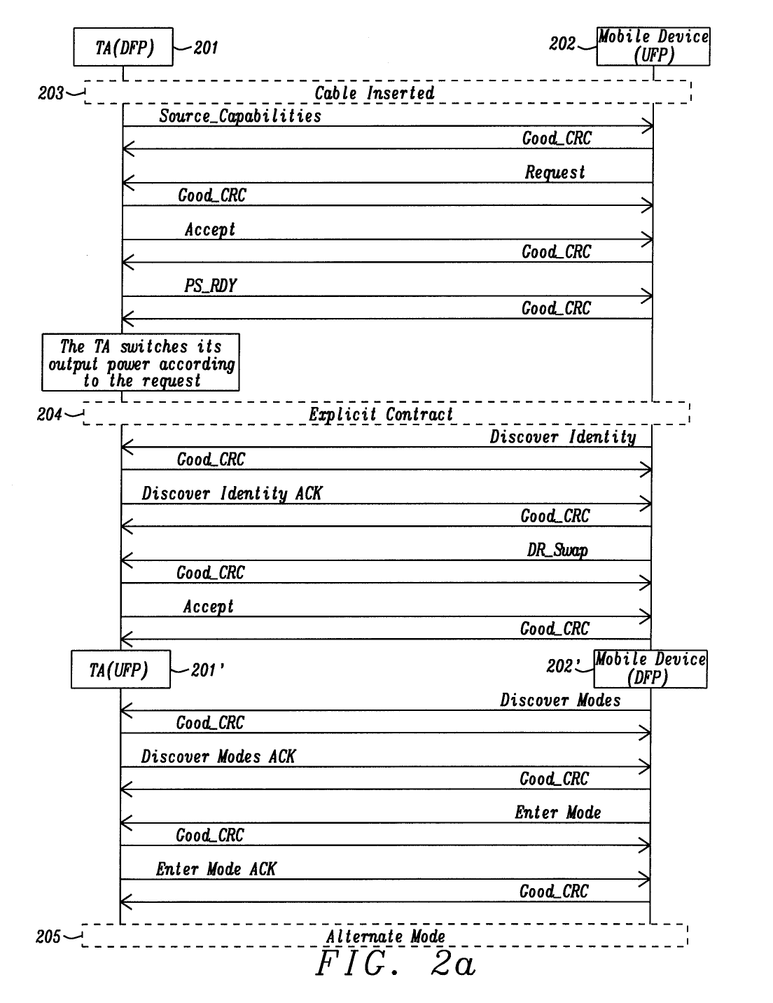

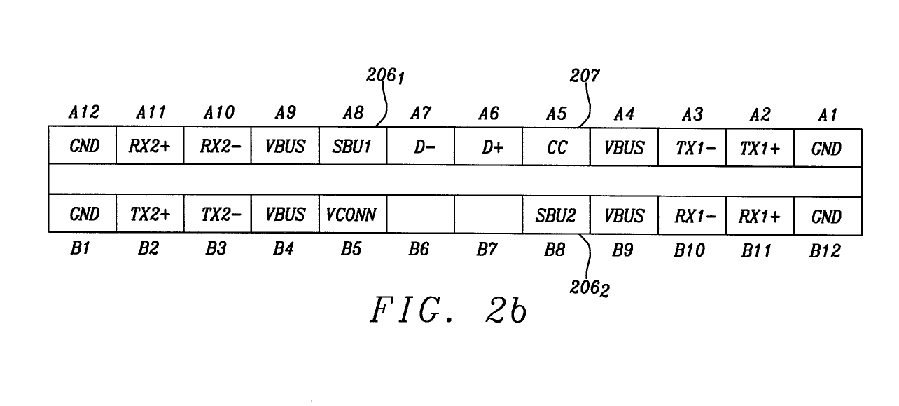

FIG. 2a schematically illustrates an example of signalling exchange procedure performed between the travel adaptor 101 and the mobile device 102 according to embodiments of the disclosure. Herein, PD communication starts after the travel adaptor 101 and the mobile device 102 have detected a cable insertion 203. After the cable insertion, the travel adaptor 101 represents a downstream facing port (DFP) 201, whereas the mobile device 102 represents an upstream facing port (UFP) 202. The terms downstream and upstream illustrate the direction of the initial data flow. The travel adaptor 101 sends a Source Capabilities Message from which the mobile device 102 discovers power levels available from the travel adaptor 101. The mobile device 102 selects a desired power level and sends a Request Message. The travel adaptor 101 accepts the request and sends a PS_RDY message after it has changed its output power accordingly. This indicates that the travel adaptor 101 and the mobile device 102 have achieved an explicit contract 204, i.e. the desired operating condition has been reached. Once a first explicit contract is achieved, the mobile device 102 can attempt vendor specified messages (VDMs). The mobile device 102 sends a Discover Identity Message with a specific vendor ID common to both the travel adaptor 101 and the mobile device 102. If the travel adaptor 101 uses the specific vendor ID, it responds with an acknowledgement, which informs the mobile device 102 that the mobile device 102 is attached to a travel adaptor that uses the common vendor ID. The mobile device 102 then proceeds to request for supported modes by sending a Discover Modes Message. If the travel adaptor 101 supports any modes, it responds with an acknowledgement that lists its modes in a format the mobile device 102 understands. Subsequently, the mobile device 102 knows whether it is connected to a travel adaptor that supports a desired alternate mode.

Since the DFP is the master for the alternate mode, the initial DFP and UFP operation may be exchanged, which can be initiated with the DR_Swap Command. The travel adaptor 101 may respond with an accept message, after which the travel adaptor 101 and the mobile device 102 will change operational roles as denoted by 201′ and 202′. However, the travel adaptor 101 remains as the source of power. The mobile device 102 sends an Enter Mode Command to the travel adaptor 101. The travel adaptor 101 switches to the desired alternate mode and responds with an acknowledgement. By this way, entry to an alternate mode can be triggered by VDMs, and the mobile device 102 and the travel adaptor 101 both switch to the alternate mode that allows using the USB signals for other purposes than their original purpose. It should be noted that these communications between the travel adaptor 101 and the mobile device 102 may be performed digitally via a Configuration Channel port of the USB type C receptacle 107. FIG. 2b illustrates an example of a port arrangement of the USB type C receptacle 107 according to embodiments of the disclosure. A1-A12 and B1-B12 represent ports (pins) that receive signals from the travel adaptor 101 and/or send signals to the travel adaptor 101. In particular, some of the ports (pins) may be digital data ports for receiving/sending digital signals, while some of the ports (pins) may be analog data ports for receiving/sending analog signals. For example, digital communication as indicated above may be performed via the Configuration Channel (CC) port 207 located at A5. Furthermore, analog signals such as sideband use (SBU) signals may be received/sent via the SBU ports located at A8 and B8 of the USB type C receptacle 107 (i.e. via SBU1 206₁ and SBU2 206₂ respectively).

It is further appreciated that one or more ports (pins) of the USB type C receptacle 107 may be available for functional reconfiguration (reconfigurable ports, e.g. the TX and RX ports as well as the SUB ports) after entering an alternate mode. That is, the signals which are received/sent via these reconfigurable ports may be reassigned in an alternate mode. For example, the Display Port protocol can be executed over a Type-C cable by using an alternate mode where the TX and RX lines of USB 3.1 are used for the DisplayPort lane signals and the SBU signals are used for DisplayPort AUX signals.

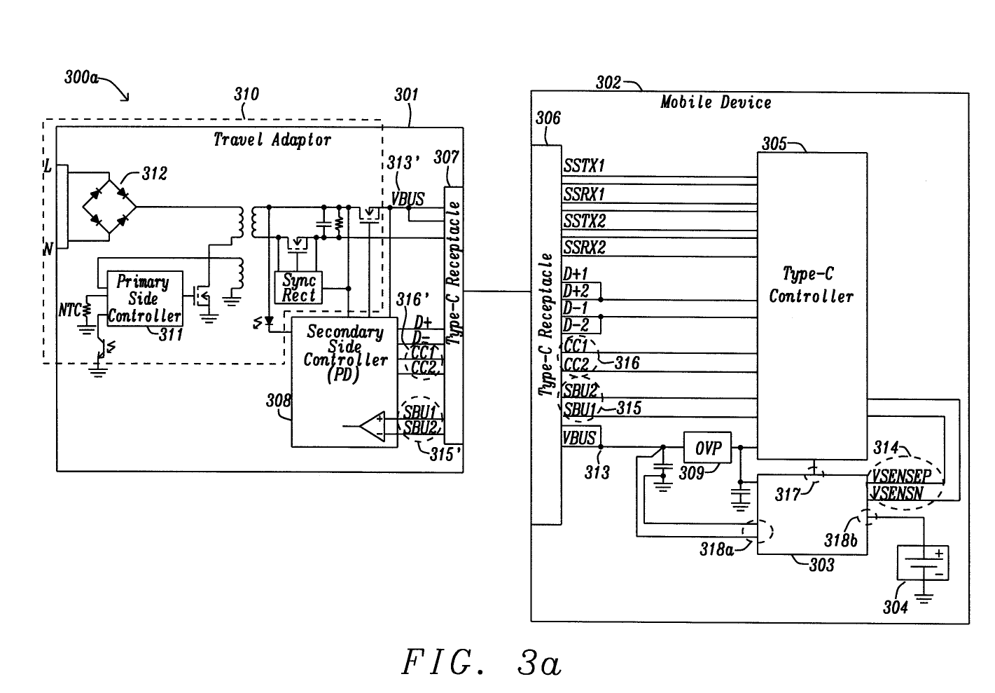

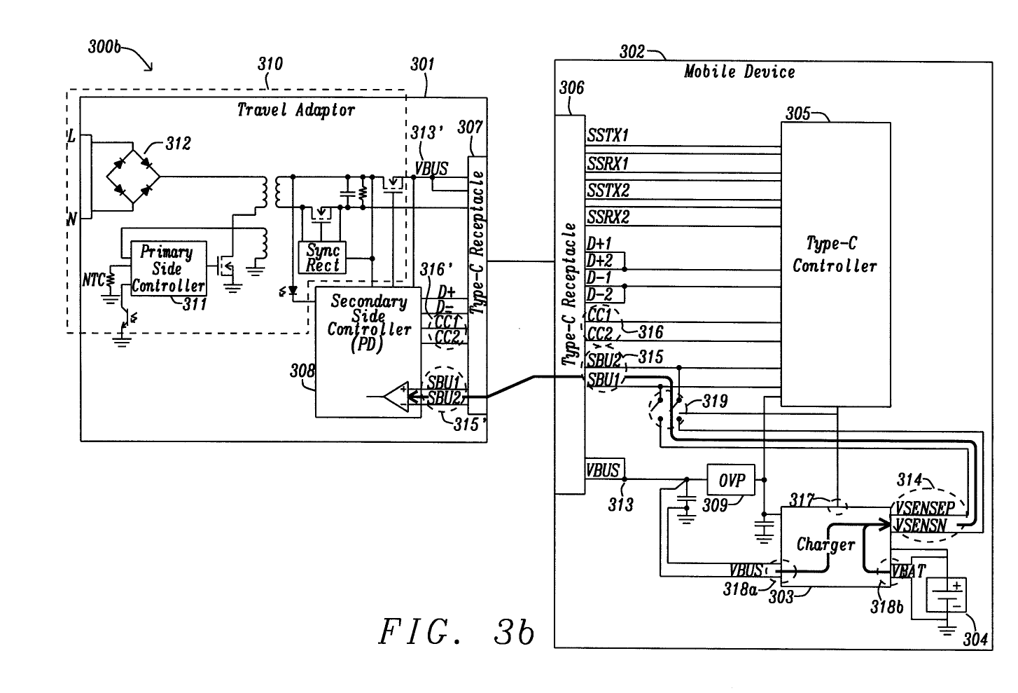

FIG. 3a schematically illustrates an example of a battery charging system according to embodiments of the disclosure. The battery charging system 300a may be similar to the charging system 100 of FIG. 1 (e.g. FIG. 1a, FIG. 1b) and includes a power adaptor 301 (e.g. a travel adaptor) and an electronic device 302 (e.g. a mobile device). In general, the power adaptor 301 is coupled with the mobile device 302 and is suitable for charging a battery 304 of the mobile device 302. As mentioned above, the mobile device 302 may be a USB Type C device having a USB Type C receptacle 306 as an interface for communicating with an external device, e.g. the power adaptor 301 which also has a USB Type C receptacle 307. Thus, the mobile device 302 is connected to the power adaptor 301 for data/power transmission via the interfaces, i.e. the USB Type C receptacles 306, 307, through a USB cable. For example, the power adaptor 301 provides a USB supply voltage V_{BUS} via the USB Type C receptacles 306, 307 to the mobile device 301 for battery charging. The USB Type C receptacles 306, 307 may have a similar pin arrangement as the USB type C receptacle 107.

In more detail, the mobile device 302 includes a USB controller 305 and a charging control unit 303 (e.g. a charger IC) which is coupled with the USB Type C receptacle 306 and the battery 304. The USB controller 305 is coupled with the USB Type C receptacle 306 and the charger 303. The charger 303 has a control input 317 which receives a control signal from the USB controller 305. Moreover, the charger 303 may have a power input port 318a which is coupled with the USB supply voltage V_{BUS} and a battery charging port 318b which is coupled with the battery 304. As mentioned, the charging system 300a can operate in a direct charging mode using a power switch or a high efficiency fixed scaler (similar to the switch 105a of FIG. 1a and the fixed scaler 105b of FIG. 1b, respectively, not shown in FIG. 3) for a bypass path. The charger 303 may have a direct charging switch driving port (not shown) to provide/control a drive signal to the power switch to enable direct charging of the battery 304 from the USB supply voltage VBus provided by the power adaptor 301. When the power switch is on, the USB supply voltage V_{BUS} is directly provided to the battery 304 through the bypass and the charging system 300a is operated in a direct charging mode. When the power switch is off, the USB supply voltage V_{BUS} may be provided to the charger 303 and the charger 303 may have a battery charging unit (not shown) to generate a battery charging voltage V_{BAT} according to the USB supply voltage V_{BUS} (operating in a normal charging mode). The charger 303 may further include a voltage protection unit 309 for preventing the battery charging unit from generating a battery charging voltage V_{BAT} in case the USB supply voltage V_{BUS} is higher than a protection threshold. Alternatively, in case of operating in the direct charging mode using a fixed scaler, the charger 303 may have a port for controlling the fixed scaler to implement direct charging of the battery 304 from the USB supply voltage VBUS provided by the power adaptor 301.

The charger 303 also has one or more sensing input ports for sensing an analog charging parameter of the battery charging system (e.g. the battery 304). The analog charging parameter can be a charge voltage or a charge current which reflects an instant charging condition of the battery 304. For example, when the charging system 300a is operated in a charging mode (e.g. a direct charging mode or a normal charging mode), the power input port 318a may be used to sense the USB supply voltage V_{BUS}, and the battery charging port 318b may be used to sense the battery charging voltage V_{BAT}. The charger 303 also has a sensing output port 314 for providing an analog sensing output signal to the USB Type C receptacle 306. The analog sensing output signal may be output to the power adaptor 301 via the USB Type C receptacles 306, 307. It should be noted that the charging parameter sensed at the sensing input port(s) 318a, 318b may be further output to the sensing output port 314. In particular, the charger 303 includes a control logic (not shown) for coupling the sensing input port(s) 318a, 318b with the sensing output port 314.

According to some embodiments, if a plurality of sensing input ports are considered, the charger 303 may select one of the sensing input ports 318a, 318b to output its sensing input signal which carries a corresponding analog charging parameter to the sensing output port 314. In particular, the charger 303 includes a switching unit (not shown) which is coupled with the sensing input ports 318a, 318b and the sensing output 314 and is controlled by the control logic to select one of the sensing input ports 318a, 318b for passing a selected sensing input signal (corresponding to a selected charging parameter) to the sensing output port 314. Accordingly, the selected sensing input signal may be associated with the USB supply voltage V_{BUS} and/or the battery charging voltage V_{BAT}. Also, the switching unit may be controlled by the control logic based on the control signal received from the USB controller 305.

The USB Type C receptacles 306, 307 for connecting the mobile device 302 with the power adaptor 301 comprise a power supply port 313, 313′ (located at A4, A9, B4, B9 according to the pin arrangement shown in FIG. 2b) for providing the USB supply voltage V_{BUS}. As mentioned, the USB Type C receptacles 306, 307 comprise at least one analog data port 315, 315′ for receiving/sending an analog data signal and at least one digital port 316, 316′ for receiving/sending a digital data signal. For example, the USB controller 305 may communicate with the power adaptor 301 using a USB protocol via a digital data port of the USB Type C receptacles 306, 307 (e.g. a Configuration Channel CC port 316, 316′). The power adaptor 301 may also receive a digital control signal from the USB controller 305 via a digital data port of the USB Type C receptacles 306, 307 to control the charger 303 (e.g. by sending a control signal to the charger based on USB commands carried by the digital control signal). It is further appreciated that the mobile device 302 is operated in an alternate mode entered based on digital communication between the USB controller 305 and the power adaptor 301 via a digital data port of the USB Type C receptacles 306, 307 (e.g. via a CC port 316, 316′ according to the communication procedure as described in FIG. 2a).

Moreover, the USB controller 305 may receive and forward the charging parameter sensed at the charger 303 (which is carried by an analog signal, e.g. a sideband use SBU signal) to the power adaptor 301 via the analog data port(s) of the USB Type C receptacles 306, 307 (e.g. a sideband use (SBU) port 315, 315′). It should be noted that a multiplexer (not shown) may be applied to multiplex the analog signals which carry the charging parameters from the USB controller 305 to be forwarded to the analog data port(s) of the USB Type C receptacles.

According to the embodiment, the power adaptor 301 includes a power converter 310 and a controller 308. The power converter 310 comprises a power controller 311 and a bridge rectifier 312 to convert a mains voltage to the USB supply voltage V_{BUS}. The controller 308 is applied to control the power converter 310 to allow (direct) charging of the battery 304. In particular, the controller 308 is coupled to the analog data port(s) of the USB Type C receptacle 307 (e.g. the SBU port(s) 315′) to receive the analog charging parameter(s) of the battery 304. It should be noted that the controller 308 may control the power converter 310 during (direct) charging of the battery 304 based on the analog charging parameter(s). Furthermore, the controller 308 may also include a USB controller similar to the USB controller 305 or the controller 308 may also perform functions similar to those performed by the USB controller 305, e.g. digitally communicating a control signal between the power adaptor 301 and the mobile device 302. Similar to the mobile device 302, the power adaptor 301 is also operated in an alternate mode entered based on the digital communication (e.g. the PD communication) between the controller 308 and the USB controller 305 via a digital data port of the USB Type C receptacles 306, 307 (e.g. via a CC port 316, 316′ according to the communication procedure as described in FIG. 2a). Once the alternate mode is active, the sideband SBU signals of the Type-C cable (i.e. SBU1, SBU2) are used as differential sensing lines between the power adaptor 301 and the mobile device 302. Since the SBU signals are not necessarily to be AC-coupled, the SBU signals are suitable for voltage sensing.

In the alternate mode as proposed in the disclosure, the SBU signals are used for sensing the input voltage of the mobile device 302 (e.g. the USB supply voltage V_{BUS}). After entering the alternate mode, as described above, the mobile device 302 connects the sense lines (i.e. the sensing output port 314) to the SBU signals. The charger IC 303 connects to the remote sense nodes (coupled to the power supply port 313) close to the USB connector performed by the USB Type C receptacle 306. The input impedance of the sense lines is high enough that it does not affect the effective impedance of V_{BUS} and ground (GND). The charger 303 feeds buffered versions of the sense lines (i.e. the sensing output port 314) to inputs of the Type-C controller 305. The Type-C controller 305 detects the orientation of the Type-C plug, and is able to connect the sense lines to the correct pins of the Type-C connector (i.e. the SBU ports). On the other hand, the power adaptor 301 connects the SBU lines (the SBU ports for receiving/sending SBU signals) to a monitoring circuitry which includes the controller 308. It should be noted that the SBU lines are cross-connected in the Type-C cable, e.g. the SBU1 lines in the power adaptor end is connected to the SBU2 line in the mobile device end. By means of the monitoring circuitry, the power adaptor measures the voltage drop over the Type-C cable and connectors. The controller 308 (the secondary controller of the power adaptor 301) compares the voltage drop to a threshold value (e.g. the maximum voltage drop VMAX_DROP). If the threshold value is exceeded, the secondary side controller disconnects the V_{BUS} output.

The error condition can be detected/monitored from the mobile device in several ways. Once the power adaptor 301 disconnects the V_{BUS} from the primary side controller (i.e. the power controller 311) the cable current will drop to zero. Even though the V_{BUS} voltage at the mobile device end may not drop to zero, the USB supply voltage settles to a voltage defined by the battery voltage due to direct charging. However, the mobile device 302 can still detect that the V_{BUS} is disconnected from the dropping cable current which may be detected by the mobile device 302, and the mobile device 302 may stop charging (which may be performed through the voltage protection unit 309). The fault condition may be likely caused by a broken cable, which means that the PD communication link is broken. However, if this is not the case, the mobile device 302 can detect the fault condition also by periodically checking a status register in the power adaptor 301 via vendor defined messages (VDMs). Once a fault has been detected, the mobile device 302 may fire an interrupt to inform an application processor of the mobile device 302, and a charger driver in the mobile device 302 can then decide to re-try charging with lower current.

FIG. 3b schematically illustrates an example of a battery charging system according to embodiments of the disclosure. The battery charging system 300b is similar to the battery charging system 300a. In other words, the elements/units which are used in both battery charging systems 300a, 300b may have the same or similar functions and therefore the corresponding explanations are not repeated herein for simplicity. However, it should be noted that the sensing output port 314 of the charger 303 in the charging system 300b is directly connected to the SBU port(s) 315 of the USB Type C receptacle 306 (via a switch 319) without passing to the USB controller 305 so that the analog charging parameter(s) is/are directly output to the SBU port(s) 315 instead of being forwarded by the USB controller 305.

As mentioned above, the alternate modes of USB Type-C allow using the USB signals to be used for other purposes than performing their original USB function, which lends itself for alternate mode implementation to achieve safe fast charging. In particular, using a connection of USB Type-C sideband signals between the USB input of the mobile device and a controller in the power adaptor, the power adaptor can apply a monitoring function that shuts down the power adaptor when an abnormal voltage drop over the charging cable is detected. In other words, the USB signals are used for monitoring the input voltage of the mobile device from the secondary side of the power adaptor.

As such, a safety feature for fast charging systems can be implemented by using the alternate mode of USB Type-C specification as described above. With the monitoring function, the power adaptor is able to implement an autonomous safety feature that disables the power adaptor in case an abnormal voltage drop over the cable is detected.

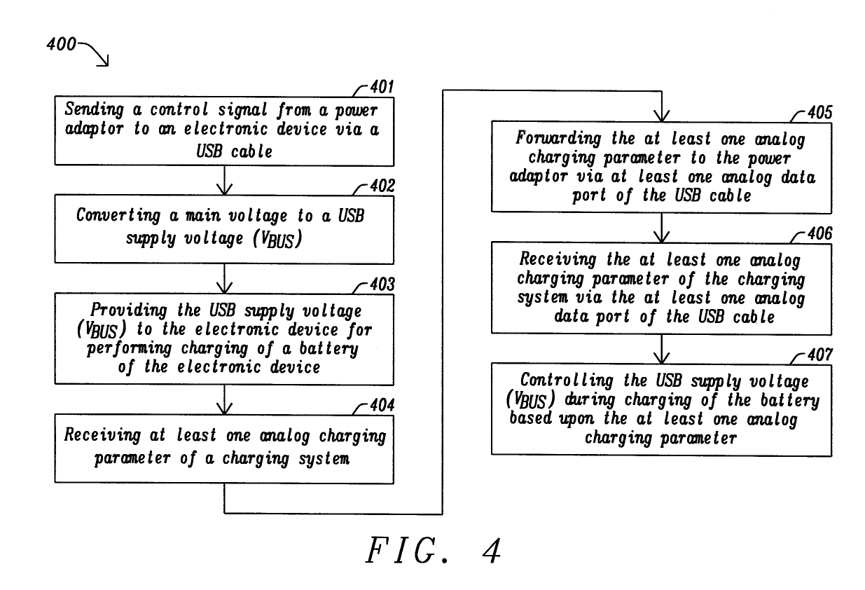

FIG. 4 illustrates processing steps for a proposed battery charging method according to embodiments of the disclosure. The method 400 can be implemented in a battery charging system, e.g. the battery charging systems 300a, 300b as described above. The method 400 comprises sending (step 401) a control signal from an electronic device to a power adaptor via a USB cable. The method 400 comprises converting (step 402), at the power adaptor, a mains voltage to a USB supply voltage (V_{BUS}) and providing (step 403) the USB supply voltage (V_{BUS}) to the electronic device via the USB cable for performing charging of a battery of the electronic device. The method 400 further comprises receiving (step 404), at the electronic device, at least one analog charging parameter of the battery charging system and forwarding (step 405) the at least one analog charging parameter to the power adaptor via at least one analog data port of the USB cable. The method 400 also comprises receiving (step 406), at the power adaptor, the at least one analog charging parameter of the battery charging system via the at least one analog data port of the USB cable and controlling (step 407), at the power adaptor, the USB supply voltage (V_{BUS}) during charging of the battery based upon the at least one analog charging parameter.

It should be noted that the device features described above correspond to respective method features that may however not explicitly be described, for reasons of conciseness. The disclosure of the present document is considered to extend also to such method features.

It is appreciated that implementing the cable monitoring on the travel adaptor side improves the safety further, because shutting down the charging system in the event of a safety hazard does not rely on monitoring circuitry on the mobile device side and communication between the mobile device and the travel adaptor. As such, the proposed feature does not introduce any disturbance to the system, it does not require proprietary cables or connectors, and it is 100% compatible with USB standards.

In particular, the proposed devices and methods introduce a reliable monitoring feature in the travel adaptor side that detects an abnormal voltage drop over the charging cable and automatically disables the travel adaptor without involvement from the mobile device.

For mobile devices that utilize high charging currents and operate close to the maximum current ratings of the charging cable and connectors and thus require additional safety measures to detect safety hazards related to the cables and connectors, the proposed devices and methods provide safety measures which are more effective, because they are implemented autonomously in the travel adaptor side without relying on monitoring functions on the mobile device side and communication between the travel adaptor and the mobile device. The safety features according to the disclosure are more easily adapted to systems when they don't use proprietary connectors and cables.

It should be noted that the description and drawings merely illustrate the principles of the proposed methods and devices. Those skilled in the art will be able to implement various arrangements that, although not explicitly described or shown herein, embody the principles of the invention and are included within its spirit and scope.

Furthermore, all examples and embodiment outlined in the present document are principally intended expressly to be only for explanatory purposes to help the reader in understanding the principles of the proposed methods and devices. Furthermore, all statements herein providing principles, aspects, and embodiments of the invention, as well as specific examples thereof, are intended to encompass equivalents thereof.

What is claimed is:

1. A control unit for monitoring charging of a battery of an electronic device, the control unit comprising:
a control input for receiving a control signal from a USB controller of the electronic device;
at least one sensing input port for sensing an analog charging parameter of the battery;
a sensing output port for providing an analog sensing output signal to a USB interface for connecting the electronic device with a power adaptor; and
a control logic for effecting, upon receiving the control signal, coupling the at least one sensing input port with the sensing output port.

2. The control unit of claim 1, comprising a plurality of sensing input ports and a switching unit coupled with the plurality of sensing input ports and the sensing output port, the switching unit controlled by the control logic to select one of the sensing input ports and to pass a selected sensing input signal to the sensing output port, the control logic controlling the switching unit based upon the control signal.

3. The control unit of claim 1, comprising a direct charging switch driving port for providing a drive signal to a power switch of the electronic device to enable direct charging of the battery from a USB supply voltage, and/or comprising a fixed scaler or a port for controlling the fixed scaler to implement direct charging.

4. The control unit of claim 2, comprising a power input port coupled with a USB supply voltage, a battery charging unit for generating a battery charging voltage, and a battery charging port coupled with the battery for charging the battery.

5. The control unit of claim 2, wherein the selected sensing input signal is associated with a USB supply voltage and/or a battery charging voltage .

6. The control unit of claim 4, further comprising a voltage protection unit for preventing the battery charging unit from generating a battery charging voltage in case the USB supply voltage is higher than a protection threshold.

7. The control unit of claim 1, wherein the USB controller is a USB type C device operating in an alternate mode.

8. A charging arrangement for charging a battery of an electronic device, the charging arrangement comprising:
a USB interface for connecting the electronic device via a USB cable with a power adaptor, the USB interface comprising a power supply port providing a USB supply voltage and at least one analog data port; and
a charging control unit coupled with the USB interface and the battery, the charging control unit receiving at least one analog charging parameter of the battery and forwarding the at least one analog charging parameter to the at least one analog data port of the USB interface, the charging control unit controlled by a control signal received via the USB interface.

9. The charging arrangement of claim 8, further comprising a power switch to enable direct charging of the battery from the USB supply voltage, the power switch controlled by the charging control unit.

10. The charging arrangement of claim 8, further comprising a USB controller coupled with the USB interface and the charging control unit, the USB controller communicating with the power adaptor via a USB protocol and controlling the charging control unit based upon received USB commands.

11. The charging arrangement of claim 10, further comprising a multiplexer for multiplexing analog signals from the USB controller or the charging control unit to the at least one analog data port of the USB interface, the multiplexer controlled for forwarding the at least one analog charging parameter to the at least one analog data port of the USB interface.

12. The charging arrangement of claim 10, the charging control unit comprising an output port for providing the at least one analog charging parameter to the USB controller for forwarding the at least one analog charging parameter to the at least one analog data port of the USB interface.

13. The charging arrangement of claim 8, the USB interface comprising at least one digital data port, the control signal received via the at least one digital data port.

14. The charging arrangement of claim 8, further comprising a voltage protection unit for preventing the charging control unit from charging of the battery from the USB supply voltage in case the USB supply voltage is higher than a protection threshold.

15. The charging arrangement of claim 10, wherein the USB controller comprises a USB type C device operating in an alternate mode, wherein the alternate mode is entered in response to digital communication between the USB controller and the power adaptor.

16. The charging arrangement of claim 15, wherein the USB interface comprises a USB type C receptacle, wherein the at least one analog charging parameter is forwarded to the at least one analog data port of the USB interface via a sideband use (SBU) signal to be received at a SBU port of the USB type C receptacle.

17. A power adaptor for supplying power via a USB cable to an electronic device, the power adaptor comprising:
a power converter to convert a mains voltage to a USB supply voltage;
a USB interface to couple the power adaptor with the electronic device; and
a controller to control the power converter to control an output voltage and an output current limit of the power adaptor, the controller coupled to at least one analog data port of the USB interface to receive at least one analog charging parameter of the battery, the controller controlling the power converter during charging of the battery based upon the at least one analog charging parameter.

18. The power adaptor of claim 17, further comprising a USB controller to perform digital communication according to a USB protocol with the electronic device via the USB interface, the USB controller communicating one or more control signals to the electronic device for enabling and/or controlling charging of the battery.

19. The power adaptor of claim 18, wherein a control signal sent to the electronic device comprises information for selection of an analog charging parameter for being monitored and feed back by the electronic device.

20. The power adaptor of claim 17, wherein the controller is configured to modify the USB supply voltage based on the at least one analog charging parameter by controlling the power converter during charging of the battery.

21. The power adaptor of claim 17, wherein the controller is configured to measure a voltage drop across the USB cable based on the at least one analog charging parameter, wherein the controller is configured to compare the voltage drop with a threshold voltage and to disconnect the power converter from a power supply port of the USB interface in case the measured voltage drop exceeds the threshold voltage, so that the USB supply voltage is not provided to the electronic device for charging the battery.

22. The power adaptor of claim 18, wherein the power adaptor is configured to enter an USB alternate mode based upon the digital communication between the USB controller and the electronic device.

23. The power adaptor of claim 17, wherein the USB interface comprises a USB type C receptacle, wherein the at least one analog charging parameter of the battery is provided via a sideband use (SBU) signal received at a SBU port of the USB type C receptacle.

24. The power adaptor of claim 21, wherein the power converter comprises a power controller and a bridge rectifier, wherein the controller is configured to disconnect the power supply port of the USB interface from the power controller in case the measured voltage drop exceeds the threshold voltage.

25. A charging system for charging a battery of an electronic device using a power adaptor, the charging system comprising:
a first communications interface disposed at the electronic device and a second communications interface disposed at the power adaptor for connecting the electronic device via a communications cable with the power adaptor;
a charging control unit coupled with the first communications interface and the battery, the charging control unit receiving at least one analog charging parameter of the charging system and forwarding the at least one analog charging parameter to at least one analog data port of the first communications interface, the charging control unit controlled by a control signal received from the power adaptor via the first communications interface and the second communications interface;
a power converter disposed at the power adaptor to convert a mains voltage to a supply voltage to be provided to the electronic device via a power supply port of the first and the second communications interface; and
a controller disposed at the power adaptor to control the power converter to allow charging of the battery of the electronic device using the supply voltage, the controller coupled to at least one analog data port of the second communications interface to receive the at least one analog charging parameter of the battery via the first communications interface, the controller controlling the power converter during charging of the battery based upon the at least one analog charging parameter.

26. The charging system of claim 25, wherein the electronic device comprises a power switch or a fixed scaler controlled by the charging control unit to enable direct charging of the battery from the supply voltage.

27. The charging system of claim 25, further comprising a communications controller coupled with the first communications interface and the charging control unit, the communications controller communicating with the controller of the power adaptor according to a communications protocol via the first and the second communications interfaces, the control signal for controlling the charging control unit comprising commands received by the first communications interface, the communications controller further controlling the charging control unit for enabling and/or controlling charging of the battery based upon the received commands.

28. The charging system of claim 27, wherein the electronic device comprises a multiplexer for multiplexing analog signals from the first communications interface controller or the charging control unit to the at least one analog data port of the first communications interface, the multiplexer controlled by the charging control unit for forwarding the at least one analog charging parameter to the at least one analog data port of the first communications interface.

29. The charging system of claim 27, wherein the communications interfaces are USB type C devices operating in an alternate mode and the power adaptor and the electronic device enter the alternate mode based on digital communication between the communications controller and the power adaptor, wherein the at least one analog charging parameter is forwarded to the at least one analog data port of the first communications interface and is provided at the at least one analog data port of the second communications interface via a sideband use (SBU) signal, wherein the SBU signal is provided at a SBU port of the USB type C devices.

30. The charging system of claim 25, wherein the controller is configured to measure a voltage drop across the communications cable based on the at least one analog charging parameter, wherein the controller is configured to compare the voltage drop with a threshold voltage and to disconnect the power converter from a power supply port of the second communications interface in case the measured voltage drop exceeds the threshold voltage, so that the supply voltage is not provided to the electronic device for charging the battery.

31. A method for charging a battery of an electronic device using a power adaptor, the electronic device coupled with the power adaptor via a USB cable, the method comprising:
sending, from the electronic device, a control signal to the power adaptor via the USB cable;
converting, at the power adaptor, a mains voltage to a USB supply voltage and providing the USB supply voltage to the electronic device via the USB cable for performing charging of the battery of the electronic device;
receiving, at the electronic device, at least one analog charging parameter of a charging system in the electronic device;
forwarding the at least one analog charging parameter to the power adaptor via at least one analog data port of the USB cable;
receiving, at the power adaptor, the at least one analog charging parameter of the charging system via the at least one analog data port of the USB cable; and
controlling, at the power adaptor, the USB supply voltage during charging of the battery based upon the at least one analog charging parameter.

32. The method of claim 31, further comprising controlling, at the electronic device, a switch or a fixed scaler to enable direct charging of the battery from the USB supply voltage.

33. The method of claim 31, wherein the electronic device is communicates with the power adaptor via a USB power delivery protocol.

34. The method of claim 33, wherein the at least one analog charging parameter is forwarded to the at least one analog data port of the USB cable via a sideband use (SBU) signal, wherein the SBU signal is provided at a SBU port of the USB cable.

35. The method of any of claims 31, further comprising multiplexing analog signals from a USB controller or a charging control unit of the electronic device to the at least one analog data port of the USB cable.
